(19) United States
(12) Patent Application Publication
(10) Pub. No.: US 2002/0062790 A1
(43) Pub. Date: May 30, 2002

(54) Processing apparatus and processing system

(76) Inventors: Kyoko Ikeda, Nirasaki-Shi (JP); Yasuo Kobayashi, Nirasaki-Shi (JP); Noriaki Matsushima, Kanagawa-ken (JP)

Correspondence Address: Finnegan, Henderson, Farabow, Garrett & Dunner, L.L.P., 1300 I Street, N.W., Washington, DC, 20005-3315, US

(21) Appl. No.: 09/954,034

(22) Filed: Sep. 18, 2001

(30) Foreign Application Priority Data
Sep. 19, 2000 (JP) 2000-284094

(51) Int. Cl. C23C 16/00

(52) U.S. Cl. 118/723 ER; 118/723 MP

(57) ABSTRACT

A processing apparatus 51 includes a processing container 53 having a wafer W arranged therein, an activated-gas seeds induction port 79 for supplying activated N₂-gas and H₂-gas into the processing container 53 and nozzle orifices 105 for supplying NF₃-gas activated by both N₂-gas and H₂-gas on activation. Thus, the processing apparatus allows N₂-gas and H₂-gas to activate NF₃-gas, so that the wafer W is processed by the activated NF₃-gas. The activated-gas seeds induction port 79 and the nozzle orifices 105 are together formed in a top plate 71 of the processing container 53, realizing an uniform distribution of NF₃-gas on the object to be processed in the processing chamber.

### BACKGROUND OF THE INVENTION

1. Technical Field of the Invention

The present invention relates to a processing apparatus and a processing system.

2. Description of the Related Art

Conventionally, as a method of effectively removing natural oxidation films from fine holes formed on a wafer, there is known a surface processing method as follows.

In this method, a mixture of N₂-gas and H₂-gas is activated by means of a plasma to form seeds of activated gas and then NF₃-gas is added to the down-flow of activated gas seeds to activate NF₃-gas. Subsequently, the activated NF₃-gas reacts with the natural oxidation film on the surface of a wafer thereby to form a generative film. Next, by heating the wafer at a designated temperature, the generative film is sublimated for its removal.

As an apparatus embodying the above method, there is known a processing apparatus 11 as shown in FIG. 23. This apparatus 11 has a processing container 13 which is adapted to form a vacuum therein and in which a mounting table 15 is disposed to mount a wafer W thereon.

While, the processing container 13 is provided, in a ceiling wall thereof, with a plasma generating pipe 17 through which both N₂-gas and H₂-gas are activated by plasma and supplied into the processing container 13. Connected to a lower end of the plasma generating pipe 17 is a cover member 19 which diverges like an umbrella downwardly to allow the activated gas to fall onto the wafer W on the mounting table 15 effectively.

Inside the cover member 19, there is arranged an annular shower head 23 having a number of gas holes 21 formed therein. A injection pipe 25 is connected to the shower head 23. Through the injection pipe 25, NF₃-gas is supplied to the shower head 23 and successively supplied into the cover member 19 through the numerous gas holes 21. In this way, with a contact with the activated gas seeds of N₂-gas and H₂-gas, NF₃-gas is also activated to react with the natural oxidation film on the wafer W.

However, this processing apparatus 11 has a problem that the activation of NF₃-gas is obstructed since the activated gas seeds of N₂-gas and H₂-gas falling in the plasma generating pipe 17 strike on the annular shower head 23 to lose their activities.

Against this apparatus, there is also known a processing apparatus 31 where no obstacle is provided in a passage for activated gas seeds in view of preventing the collision of activated gas seeds while and NF₃-gas is introduced into the processing container through its sidewall.

As shown in FIG. 24, this processing apparatus 31 also includes the processing container 13 in which the mounting table 15 is disposed to mount the wafer W thereon. Connected to the ceiling wall of the processing container 13 is a lower end of a plasma generating pipe 33 through which N₂-gas and H₂-gas activated by plasma are supplied into the processing container 13.

Further, the processing container 13 is provided, on a peripheral wall thereof, with a number of nozzles 35 through which NF₃-gas is supplied into the processing container 13. Then, on contact with the activated gas seeds of N₂-gas and H₂-gas descending from the upside, NF₃-gas is activated to react with the natural oxidation film on the wafer W.

In the processing apparatus 31, however, NF₃-gas is supplied from an outer wall of the apparatus toward its interior side in the horizontal direction while both N₂-gas and H₂-gas descend from the upside of the apparatus. Therefore, a problem arises in that the distribution of NF₃-gas in the processing container 33 becomes uneven to cause an uneven processing for the wafer W. In detail, as apparent from FIG. 26 which illustrates a result of analyzing the distribution of NF₃-gas in a processing container shown in FIG. 25 by means of computer simulation, a high-density area of NF₃-gas is formed in the periphery of the interior of the processing container 13, so that an uneven density of NF₃-gas is established on the surface of the wafer W.

### SUMMARY OF THE INVENTION

In order to solve the above-mentioned problem, the object of the present invention is to provide a processing apparatus and also a processing system both of which allow activity of a first gas to be hardly lost when processing an object in a processing container with supply of both first gas and second gas into the processing container and which can accomplish a formation of uniform gas-distribution on the object.

The first feature of the present invention resides in a processing apparatus comprising a processing container in which an object to be processed is arranged; a first-gas supply port for supplying an interior of the processing container with a first gas on activation; and a second-gas supply port for supplying a second gas activated by the first gas, the processing apparatus allowing the first gas to activate the second gas thereby processing the object by the second gas on activation; wherein the first-gas supply port and the second-gas supply port are formed in an opposite wall forming the processing container, the opposite wall being arranged so as to face the object to be processed.

The second feature of the present invention resides in that the first-gas supply port is arranged so that a direction of gas ejected through the first-gas supply port points to a center portion of the object to be processed, and the second-gas supply ports as a plural are arranged apart from each other around the first-gas supply port in a circumferential direction thereof.

The third feature of the present invention resides in that the second-gas supply ports are arranged so that a direction of gas ejected through the second-gas supply ports extends along the direction of gas ejected through the first-gas supply port.

The fourth feature of the present invention resides in that the first-gas supply port has an inner circumferential surface close to a space in the processing container, the inner circumferential surface being tapered so as to gradually increase a diameter of the first-gas supply port as approaching the space in the processing container.

The fifth feature of the present invention resides in that the second-gas supply ports open at an inner circumferential surface of a first-gas supply port's part close to a space in the processing container.

The sixth feature of the present invention resides in that the second-gas supply ports are positioned apart from an open edge of the first-gas supply port but less than 65 mm therefrom.

The seventh feature of the present invention resides in that the opposite wall provided with the first-gas supply port includes an opposite-wall body and a nozzle plate overlaid on an inside of the opposite-wall body; a superposition plane where the nozzle plate and the opposite-wall body are laid to overlap each other has a gas reservoir formed so as to surround the first-gas supply port annularly; the opposite-wall body has a communication hole formed to allow an outside of opposite-wall body to communicate with the gas reservoir thereby to supply the second gas to the gas reservoir; and that the nozzle plate has the second-gas supply ports formed so as to begin with the gas reservoir and also open at an inside space of the processing container.

The eighth feature of the present invention resides in that the gas reservoir is defined between the opposite-wall body and an annular recess formed in the superposition plane of the nozzle plate.

The ninth feature of the present invention resides in that the nozzle plate is detachably fixed to the opposite-wall body.

The tenth feature of the present invention resides in that the second-gas supply ports are formed so that a direction of gas ejected through the second-gas supply ports extends along the direction of gas ejected through the first-gas supply port.

The eleventh feature of the present invention resides in that the second-gas supply ports are formed to begin with the gas reservoir and also open at an inner circumferential surface of the first-gas supply port close to a space in the processing container.

The twelfth feature of the present invention resides in that the first gas is a mixture of N₂-gas and H₂-gas, while the second gas is NF₃-gas.

The thirteenth feature of the present invention resides in that the processing apparatus is adapted so as to allow the second gas to react with an oxidation film on a surface of the object to be processed thereby to produce a generative film.

The fourteenth feature of the present invention resides in a processing system for removing an oxidation film formed on an object to be processed, comprising a first processing chamber having a processing apparatus claimed in claim 13; a second processing chamber having heating means for heating the object to be processed and also allowing the heating means to heat a generative film produced in the first processing chamber up to a designated temperature for evaporation thereby removing the generative film from the object; and transfer means for transferring the object to be processed between the first processing chamber and the second processing chamber.

### BRIEF DESCRIPTION OF THE DRAWINGS

FIG. 1 is a schematic perspective view showing an embodiment of a processing system using a processing apparatus of the present invention;

FIG. 2 is a schematic longitudinal sectional view showing an embodiment of a processing apparatus of the present invention;

FIG. 3 is a plan view showing a nozzle plate used in the embodiment of FIG. 2;

FIG. 4 is a schematic view showing dimensions of respective parts of a processing container of the processing apparatus of FIG. 2;

FIG. 5 is a view showing a result of analyzing a mole fraction of NF₃-gas about the processing container of FIG. 4;

FIG. 6 is a view showing a result of analyzing a mole fraction of NF₃-gas in case of changing the position of NF₃-gas nozzle orifices about the processing container of FIG. 4;

FIG. 7 is a view showing a result of analyzing a mole fraction of NF₃-gas in case of further changing the position of NF₃-gas nozzle orifices about the processing container of FIG. 4;

FIG. 8 is a diagram showing a result of analyzing mole fractions of NF₃-gas on a wafer in respective cases of FIGS. 5, 6, 7 and FIG. 26;

FIG. 9 is a view showing a distribution of mole fraction on a wafer W in plan view;

FIG. 10 is a schematic longitudinal sectional view showing a processing container provided with inclined nozzle orifices;

FIG. 11 is a schematic perspective view showing the processing container provided with the inclined nozzle orifices;

FIG. 12 is a schematic longitudinal sectional view showing a processing container having nozzle orifices in double arrangement;

FIG. 13 is a schematic perspective view showing the processing container having the nozzle orifices in double arrangement;

FIG. 14 is a schematic plan view showing the arrangement of the nozzle orifices in the processing container of FIG. 12;

FIG. 15 is a schematic sectional view showing a processing container having vertical nozzle orifices in single arrangement;

FIG. 16 is a schematic perspective view showing the processing container having the vertical nozzle orifices in single arrangement;

FIG. 17 is a longitudinal sectional view showing a distribution of mole fraction of NF₃-gas in the processing container of FIG. 15;

FIG. 18 is a longitudinal sectional view showing a distribution of mole fraction of NF₃-gas in the processing container of FIG. 10;

FIG. 19 is a longitudinal sectional view showing a distribution of mole fraction of NF₃-gas in the processing container of FIG. 12;

FIG. 20 is a diagram view showing diametrical distributions of mole fraction of NF₃-gas in the processing containers of FIGS. 10, 12 and FIG. 15;

FIG. 21 is a plan view showing another example of a nozzle plate usable in the processing container of FIG. 2;

FIG. 22 is a sectional view taken along a line X-X of FIG. 21;

FIG. 23 is a schematic sectional view showing a processing apparatus in conventional art;

FIG. 24 is a schematic sectional view showing another processing apparatus in prior art;

FIG. 25 is a schematic view showing dimensions of respective parts of a processing container of the conventional art processing apparatus of FIG. 24; and

FIG. 26 is a view showing a result of analyzing a mole fraction of NF₃-gas about the processing container of FIG. 25.

### DESCRIPTION OF THE PREFERRED EMBODIMENT

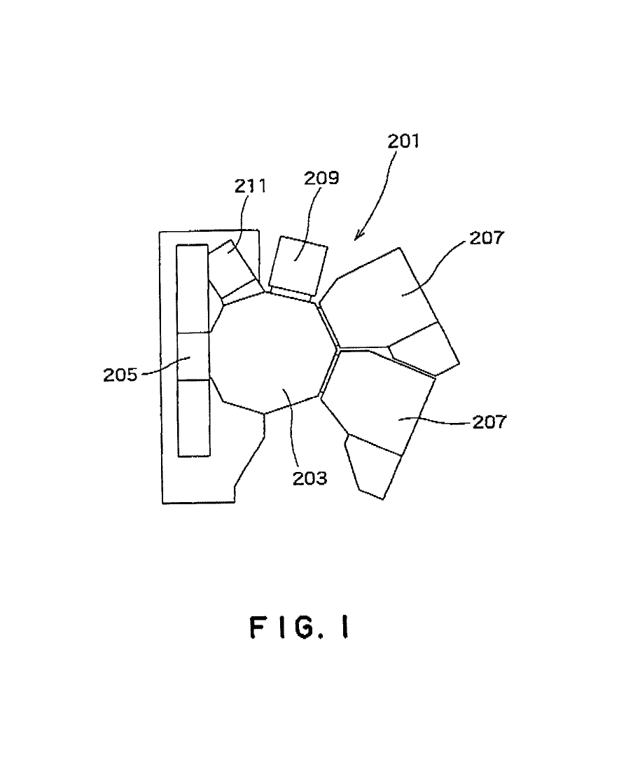

With reference to FIGS. 1 to 22, embodiments of the present invention will be described below.

FIG. 1 is a plan view of a processing system 201 as an example of processing system using a processing apparatus of the present invention. This processing system 201 is characterized by including a low temperature processing chamber and a heating chamber independently. This processing system 201 is provided, at a center thereof, with a transfer chamber 203. A wafer transfer unit is disposed in the transfer chamber 203. The interior of the transfer chamber 203 is filled up with non-reactive atmosphere, for example, vacuum in order to prevent a production of a natural oxidation film on a wafer W on transportation. A load lock chamber 205 is connected to the transfer chamber 203 to load a wafer to be processed into the chamber 203.

While, on the opposite side of the load lock chamber 205 over the transfer chamber 203, two low temperature processing chambers 207, 207 are respectively connected to the transfer chamber 203. In the low temperature processing chambers 207, each of which will be described as a processing apparatus 51 later, activated NF₃-gas reacts with the natural oxidation film on the surface of the wafer thereby to form a generative film as a mixture of the elements Si, N, H and F.

A heating chamber 209 is connected to the transfer chamber 203. Inside the heating chamber 209, there is provided heating means, for example, a known resistance-heating type stage heater which allows the wafer W to be heated. In the heating chamber 209, the wafer W after the low temperature processing is heated to a designated temperature, for example, more than 100° C., whereby the above generative film is sublimated (or vaporized). In this way, the generative film on the wafer W is eliminated.

Further, a cooling chamber 211 is also connected to the transfer chamber 203. This cooling chamber 211 is provided in order to cool the wafer after the heating process. After the heating process, the wafer used to be accommodated in a resinous cassette for unloading. However, if leaving the wafer as it is of a high temperature, there is a possibility that the resinous cassette is damaged. For this reason, the wafer is cooled before being accommodated in the cassette.

Next, the above low temperature processing chamber 207, that is, the processing apparatus 51 will be described with reference to FIGS. 2 to 22. FIG. 2 shows a section of the processing apparatus 51. The processing apparatus 51 has a processing container 53. The processing container 53 includes a container body 55 in form of a cylinder with a bottom. The container body 55 is provided, on its bottom part, with a mounting table 57 for mounting the wafer W thereon. This mounting table is provided with an elevating mechanism 59 which allows the wafer W to move up and down while pushing it up. Further, the mounting table 57 is provided with a cooling circuit 61 which allows the wafer W on the mounting table 57 to be cooled down, On the other hand, in the bottom part of the container body 55, an exhaust port 63 is provided so as to allow a gas in the processing container 53 to be discharged and evacuated into a vacuum. This exhaust port 63 is connected to a not-shown exhaust pump. A water gateway 67 is formed in the sidewall of the container body 55, also provided with a gate valve 69. The gateway 67 is connected to the transfer chamber 203 shown in FIG. 1.

Meanwhile, a top plate 71 is arranged on an upper opening of the container body 55. The top plate 71 includes a plate body 73 for covering and closing the upper opening of the container body 55, and a nozzle plate 75 detachably fitted to a lower face of plate body 73.

The plate body 73 has its outer circumference fixed to the top end of the processing container 55 through a sealing member 77 in an airtight manner. The plate body 73 is provided, at its center part, with an activated-gas seeds induction port 79 to which a plasma generating pipe 81 is connected.

The plasma generating pipe 81 is made of e.g. silica to be a pipe and also fitted to the plate body 73 in an airtight manner while standing up on the plate body 73. The plasma generating pipe 81 is provided, at its top end, with a plasma-gas induction part 83 which introduces a plasma gas consisting of N₂-gas and H₂-gas into the pipe 81. This plasma-gas induction part 83 has an induction nozzle 85 inserted into the plasma generating pipe 81 and also connected to a gas passage 87. Further, a N₂-gas source 91 filled up with N₂-gas and a H₂-gas source 93 filled up with H₂-gas are together connected to the gas passage 87 through respective flow control units 89, such as mass-flow controller.

A plasma generating part 95 is arranged just below the above induction nozzle 85. This plasma generating part 95 includes a microwave source 97 for generating a microwave of 2.45 GHz and a microwave supplier 99, such as cavity type discharge tube and Ebenson type waveguide, arranged in the plasma generating pipe 81 and is adapted so as to supply a microwave generated at the microwave source 97 into the microwave supplier 99 through a rectangular waveguide 101. In this structure, owing to the microwave on supply, a plasma is formed in the plasma generating pipe 81 to activate a mixing gas of H₂-gas and N₂-gas and further establish a down-flow of activated gas. Then, the activated-gas seeds of H₂ and N₂ are supplied into the processing container 53 through the activated-gas seeds induction port 79 downwardly.

The activated-gas seeds induction port 79 in the top plate 71 has an inner circumferential surface 80 funnel-shaped so as to gradually increase its diameter as directing downward and is also adapted so that an extension of the surface 80 encloses the wafer on the mounting table.

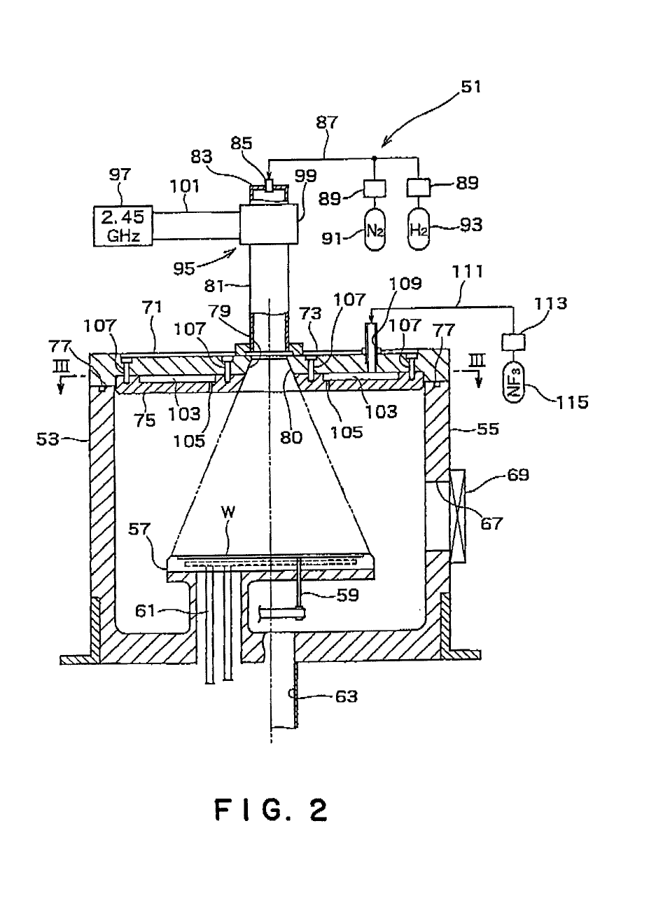

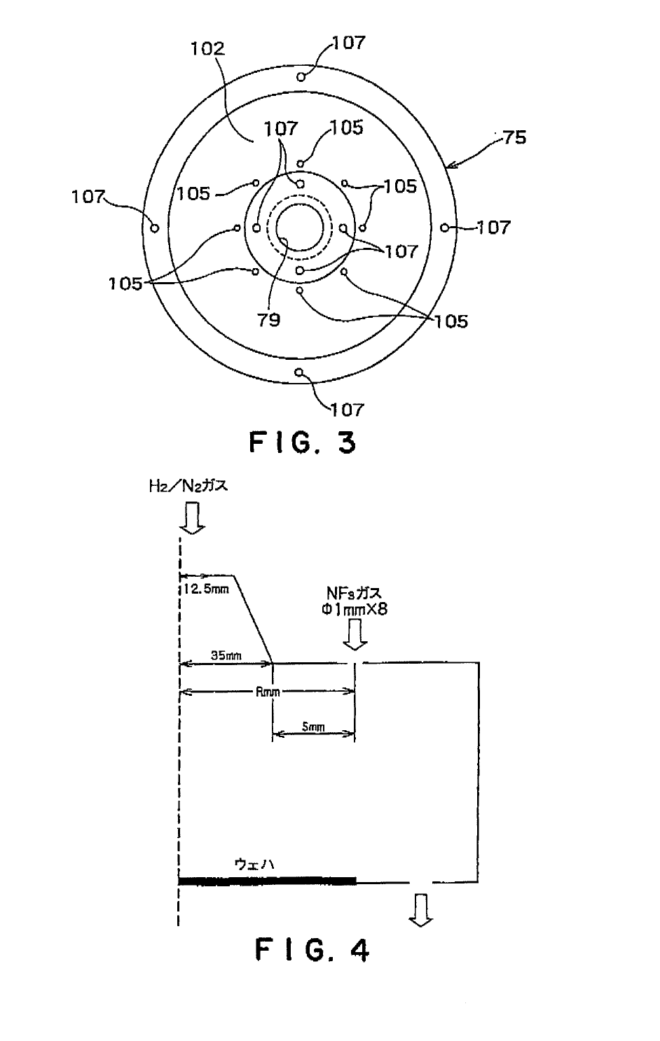

As shown in FIG. 3, the nozzle plate 75 is configured in the form of a disc which is provided, at a center thereof, with the activated-gas seeds induction port 79. On an upper face of the nozzle plate 75, an annular recess 102 formed to define a gas reservoir 103 between the top plate 71 and the nozzle plate 75. In the annular recess 102, eight nozzle orifices 105 are formed so as to encircle the activated-gas seeds induction port 79 at regular intervals in the circumferential direction, extending from the gas reservoir 103 to the lower face of the nozzle plate 75. Extending vertically downward, the nozzle orifices 105 are formed in the vicinity of the activated-gas seeds induction port 79 on the inner peripheral side of the annular recess 102. As to the position of each nozzle orifice 105 in the radial direction, it is desirable that when a radial distance between the nozzle orifice 105 and the lower edge of the above activated-gas seeds induction port 79 is represented by an alphabet S (see FIG. 4), the distance S becomes less than 65 mm. The nozzle plate 75 is detachably fixed to the plate body 75 by means of bolts 107. Therefore, if there are previously prepared a number of nozzle plates whose arrangement, distribution, ejection angles, etc. of the nozzle orifices 105 are altered variously, then it is possible to make an exchange of the nozzle plate in accordance with the change of processing conditions, such as diameter of wafer, accomplishing the most suitable processing.

On the other hand, the plate body 73 is provided, at its part facing the gas reservoir 103, with a processing-gas hole 109 which allows the processing gas to be supplied into the gas reservoir 103. A NF₃-gas source 115 filled up with NF₃-gas is connected to the processing-gas hole 109 through a gas passage 111 and a flow control unit 113.

Next, we describe a method of removing the natural oxidation film, which is carried out by using the processing system 201 constructed above.

The wafer having the natural oxidation film formed thereon is loaded from the load lock chamber 205 into the transfer chamber 203 and subsequently, this wafer is transported to the low temperature processing chamber 207, that is, the processing apparatus 51 where the so-called low temperature treatment is performed.

First, it is carried out to introduce the semiconductor wafer W as the object to be processed into the processing container 53 through the gateway 67 and continuously mount the wafer on the mounting table 57. At this time, there have been formed, on the preceding stage, contact-holes etc. on this wafer W and further produced the natural oxidation film on the surfaces of bottoms of the contact holes.

Once the wafer W is loaded into the processing container 53, the processing container 53 is closed to evacuate its interior for vacuum. Then, N₂-gas of the N₂-gas source 91 and H₂-gas of the H₂-gas source 93 are respectively introduced into the plasma generating pipe 81 through the plasma-gas induction part 83, with predetermined amounts of flowing. Simultaneously, a microwave of 2.45 GHz is produced by the microwave source 97 of the plasma generating part 95 and further led to the microwave supplier 99 and into the plasma generating pipe 81. Consequently, both N₂-gas and H₂-gas are activated into plasmas thereby to produce activated gas seeds. Since the processing container 53 is evacuated for vacuum, the activated gas seeds form a down-flow that falls in the plasma generating pipe 81 toward the activated-gas seeds induction port 79. Then, the activated gas seeds enter into the processing container 53 through the activated-gas seeds induction port 79 and successively fall toward the mounting table 57.

While, NF₃-gas is supplied from the NF₃-gas source 115 to the gas reservoir 103 through the flow control unit 113, the gas passage 111 and the processing-gas supply port 109. The NF₃-gas supplied into the gas reservoir 103 spreads all over an annular space and is supplied into the processing container 53 through the nozzle orifices 105 downwardly.

Hereat, the NF₃-gas supplied through the nozzle orifices 105 is added to the “down-flow” activated gas seeds as a mixing gas consisting of N₂-gas and H₂-gas. Consequently, the added NF₃-gas is also activated by the activated gas seeds of N₂ and H₂. In this way, since NF₃-gas is also activated, it reacts with the natural oxidation film on the wafer W together with the “down-flow” activated gas seeds, thereby forming a generative film as a mixture of the elements Si, N, H and F.

In the meantime, the processing gas of NF₃-gas flows downward while surrounding the activated gas seeds of N₂ and H₂ falling from the activated-gas seeds induction port 79, also in parallel with the activated gas seeds. Therefore, both of the processing gas and the activated gas seeds are mixed with each other efficiently and uniformly, allowing the density of activated NF₃ to be uniform on the wafer.

Then, as to the process conditions, the amounts of flowing of H₂, N₂ and NF₃ are 30 sccm, 150 sccm and 1400 sccm, respectively. The other conditions are 4 Torr (530 Pa) in process pressure, 400 W in plasma power and 1 min. in process time. In this way, the generative film as a result of the reaction with the natural oxidation film is formed on the surface of the wafer.

After completing the formation of the generative film, it is carried out to stop the supply of gases of H₂, NF₃ and N₂ and also the drive of the microwave source 97, and further evacuate the processing container 53 to remove a residual gas therein. Thereafter, the wafer W is discharged from the processing container and successively loaded into the heating chamber 209 through the transfer chamber 203. In the heating chamber, the wafer W after the low temperature process is heated to a predetermined temperature, for example, more than 100° C. owing to this heating operation, the above generative film is sublimated (i.e. evaporation), that is, the natural oxidation film on the wafer W is eliminated so that a surface of Si appears on the surface of the wafer. Note, the then process conditions are 0.7 Torr (93 Pa) in process pressure and 1 min. or so in process time. Subsequently, the heated wafer is transferred to the cooling chamber 211. After cooling the wafer there, it is accommodated in the cassette for unloading. Thus, it is possible to prevent the resinous cassette from being damaged by the wafer of high temperature.

Next, we describe a result of analyzing the computer-simulation about the density of gas in the processing container 53 of the processing apparatus 51 in this embodiment.

FIG. 4 shows dimensions of a processing container assumed in this analysis. Previously to the analysis, we first assumed three kinds of processing containers having different values in terms of a distance R between the center of the activated-gas seeds induction port and the nozzle orifice. Further, we analyzed a mole fraction of NF₃-gas in the processing container in case of introducing the activated gas seeds of N₂ and H₂ through the activated-gas seeds induction port under the above-mentioned process conditions and also supplying NF₃-gas through the nozzle orifices.

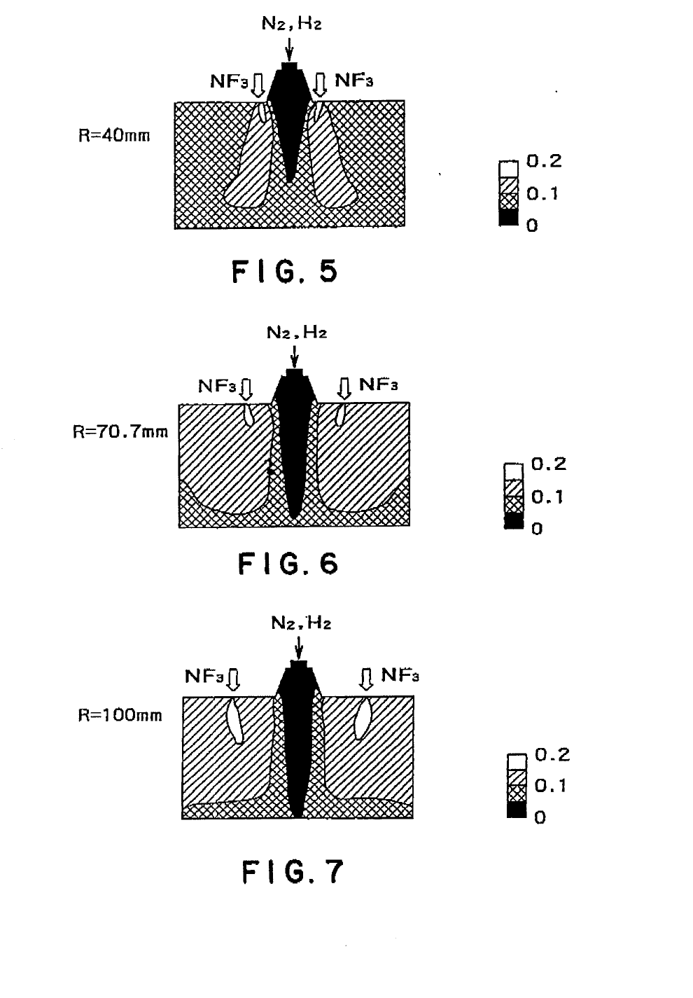

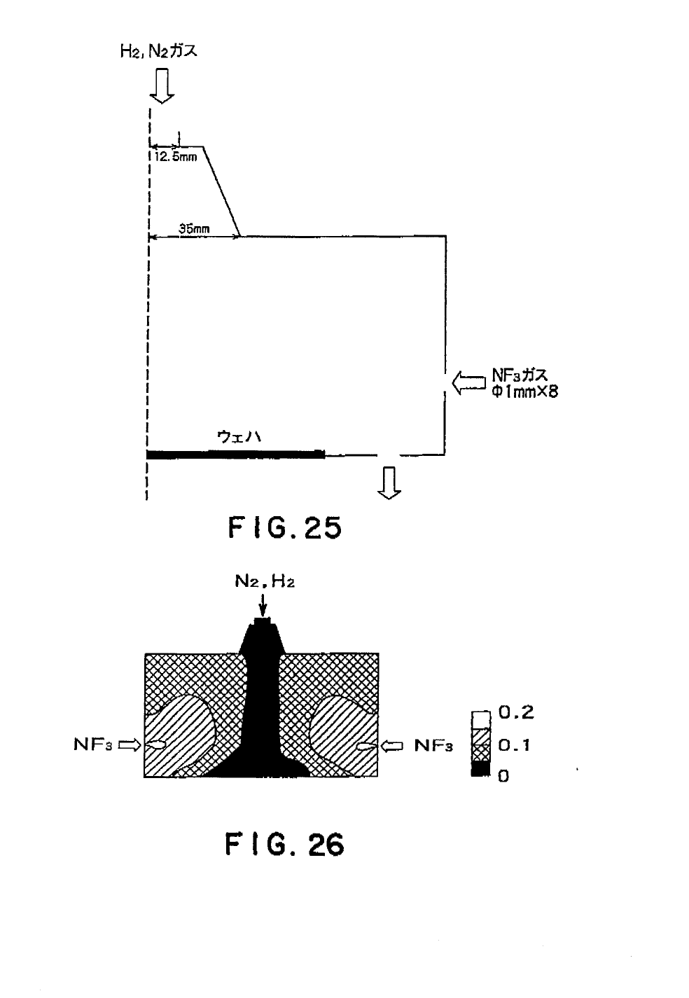

FIG. 5 shows the analysis result in case of 40 mm in the distance R, FIG. 6 shows the analysis result in case of 70.7 mm in the distance R, and FIG. 6 shows the analysis result in case of 100 mm in the distance R. While, FIG. 26 shows the analysis result in case of providing the nozzle orifices for NF₃-gas in the sidewall of the processing container, as shown in FIG. 25. As obvious from the comparison among these figures, FIG. 26 of the prior art illustrates a situation that the mole fraction of NF₃-gas on the processed surface of the wafer of 200 mm in diameter is within a range from 0 to 0.1, while FIGS. 5 to 7 of the present invention illustrates a situation that the mole fraction is within a range from 0.05 to 0.1, representing an uniform density of NF₃-gas on the processed surface of the water.

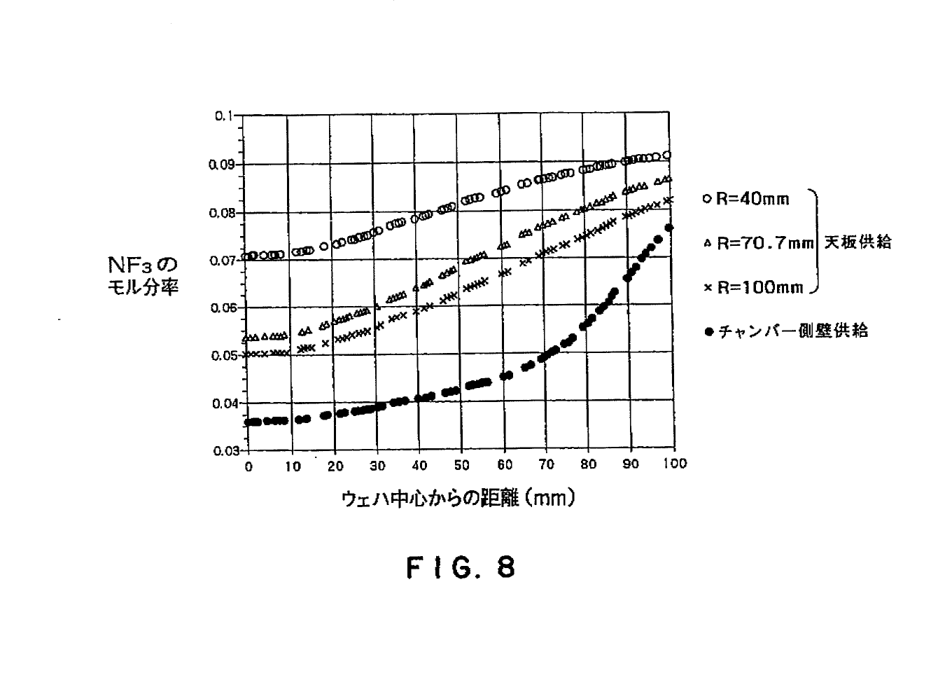

Further, FIG. 8 shows the result of analyzing the mole fraction of NF₃-gas on the wafer surface in respective cases of FIG. 5 (R=40 mm), FIG. 6 (R=70.7 mm), FIG. 7 (R=100 mm) and FIG. 26 (where the supply ports of NF₃-gas of FIG. 25 are formed in the sidewall of the processing container). In this figure, a horizontal axis designates a distance from the wafer's center, also showing how the mole fraction is changed as being apart from the wafer's center.

As apparent from this figure, in both cases of FIGS. 25 and 26, that is, case of forming the supply ports for NF₃-gas in the sidewall of the container, it is found that the mole fraction at the wafer's periphery differs from the same at the wafer's center greatly, i.e., more than double. To the contrary, in cases of 40 to 100 in the distance R (FIGS. 5 to 7), there are found remarkable reductions in terms of the difference between the mole fraction at the wafer's center and the same at the wafer's periphery.

In this way, owing to the provision of the nozzle orifices 105 for NF₃-gas in the top plate 71, the processing apparatus 51 is capable of remarkable improvement in the uniformity of NF₃-gas density on the wafer W.

As a result of comparing FIGS. 5 to 7 with each other, it is also found that the mole fraction of NF₃-gas on the wafer surface is within a range from 0.05 to 0.1 in common with these three cases. Nevertheless, it should be noted that the area of mole fraction from 0 to 0.05 reaches the wafer surface in case of FIG. 7. Therefore, the case of FIG. 7 has a tendency for the density at the wafer's center to decrease in comparison with both cases of FIGS. 5 and 6. From this, it is found that the distance R less than 70.7 mm is desirable for the position of NF₃-gas nozzle, in other words, it is desirable that a distance S (see FIG. 4) between the opening edge of the activated-gas seeds induction port 79 and each nozzle orifice 105 for NF₃-gas is less than 35.7 mm.

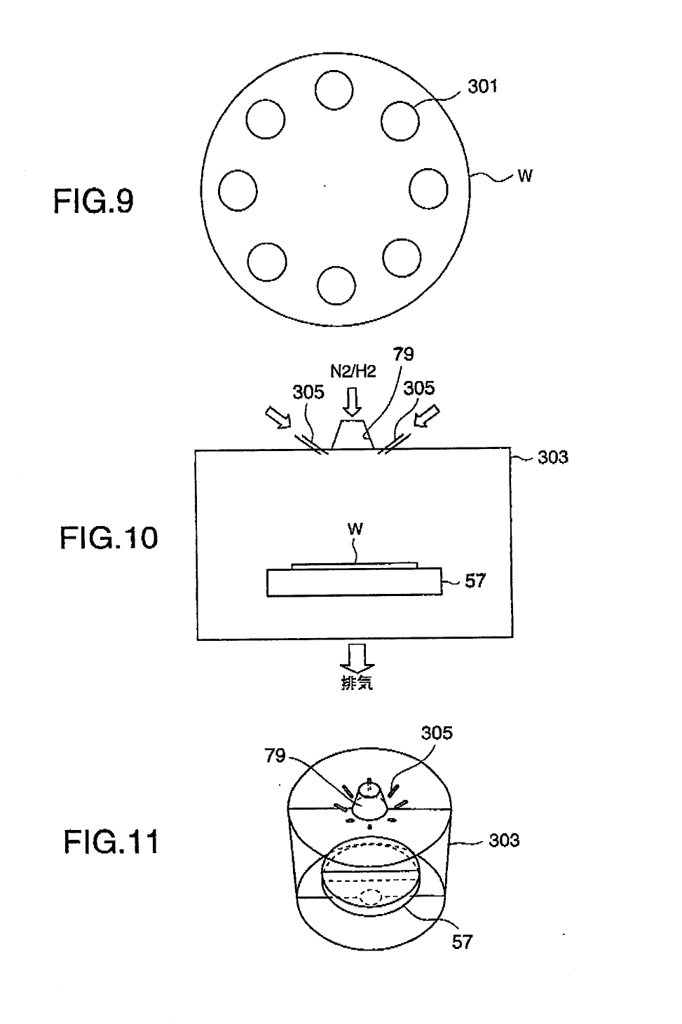

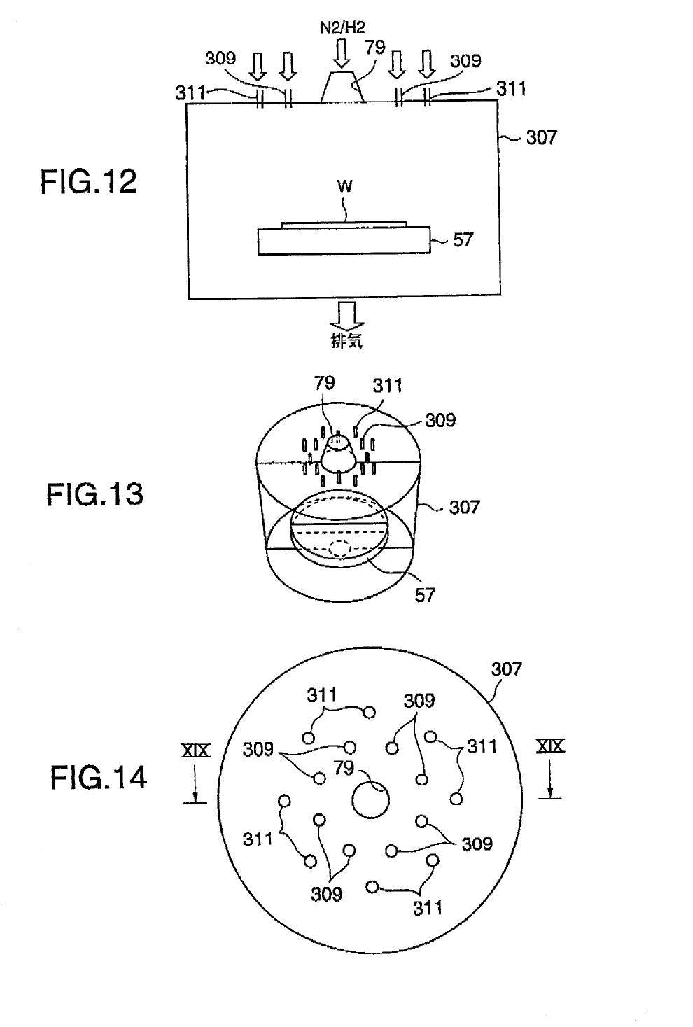

In this way, if adopting the arrangements of nozzle orifices shown in FIGS. 5 and 6, there can be accomplished appropriate distribution of mole fraction on the wafer in the radial direction. In the distribution of NF₃-mole fraction on the wafer W in plan view, however, there is a possibility that uneven spots 301 shown in FIG. 9 are produced corresponding to the nozzle orifices. Therefore, in order to prevent the occurrence of the uneven spots 301, there have been developed one processing container as shown in FIGS. 10 and 11 and another processing container as shown in FIGS. 12 and 13. In the processing container 303 of FIG. 10, nozzle orifices 305 are formed with inclinations so as to direct radially inward as they extend downwardly. The nozzle orifices 305 are formed to each have an inner diameter of 1 mm and arranged at regular intervals in the circumferential direction of the container, at eight positions. Each nozzle orifice 305 crosses the horizontal plane at an angle of 30°. Further, each nozzle orifice is arranged in a position of 55 mm in the radius R from the center of the activated-gas seeds induction port 79 to the nozzle orifice's opening to the processing container.

The processing container 307 shown in FIG. 12 includes eight inner nozzle orifices 309 apart from each other in the circumferential direction, each of which has an inner diameter of 1 mm, and eight outer nozzle 311 apart from each other in the circumferential direction, each of which has an inner diameter of 1 mm, as well. Additionally, as shown in FIG. 14, the inner nozzle orifices 309 and the outer nozzle orifices 311 are alternately arranged in respective positions shifted from each other by 12.5° in the circumferential direction.

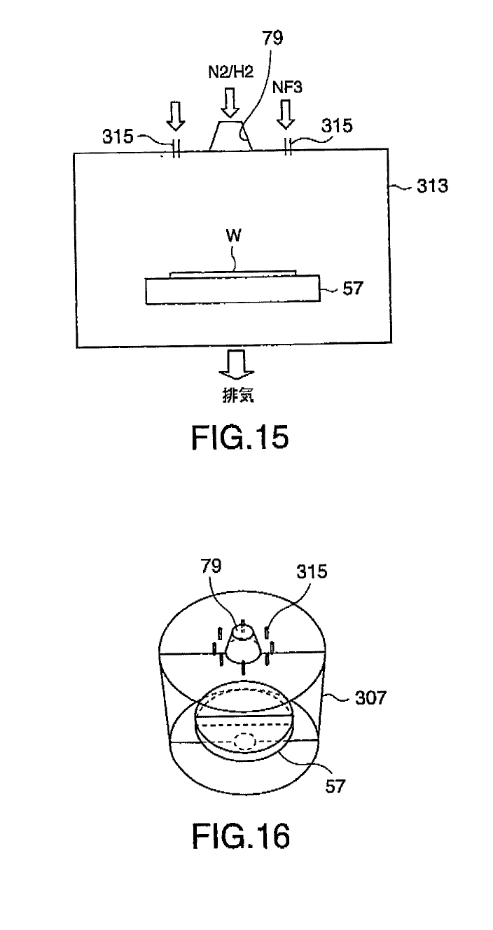

On the other hand, as the processing apparatus corresponding to the processing apparatus of FIGS. 5 and 6, there has been supposed a processing apparatus 313 as shown in FIGS. 15 and 16. The processing apparatus 313 is provided, in the circumferential direction, with eight nozzle orifices 315 of 1 mm in inner diameter.

For three processing apparatuses shown in FIGS. 10, 12 and 15, we have analyzed their inside NF₃ density by means of computer-simulation.

Consequently, it is found that the processing apparatus 303 having the slanted nozzle orifices of FIG. 10 does not produce the uneven spots in the distribution of mole fraction, which correspond to the nozzle positions respectively, as shown in FIG. 9.

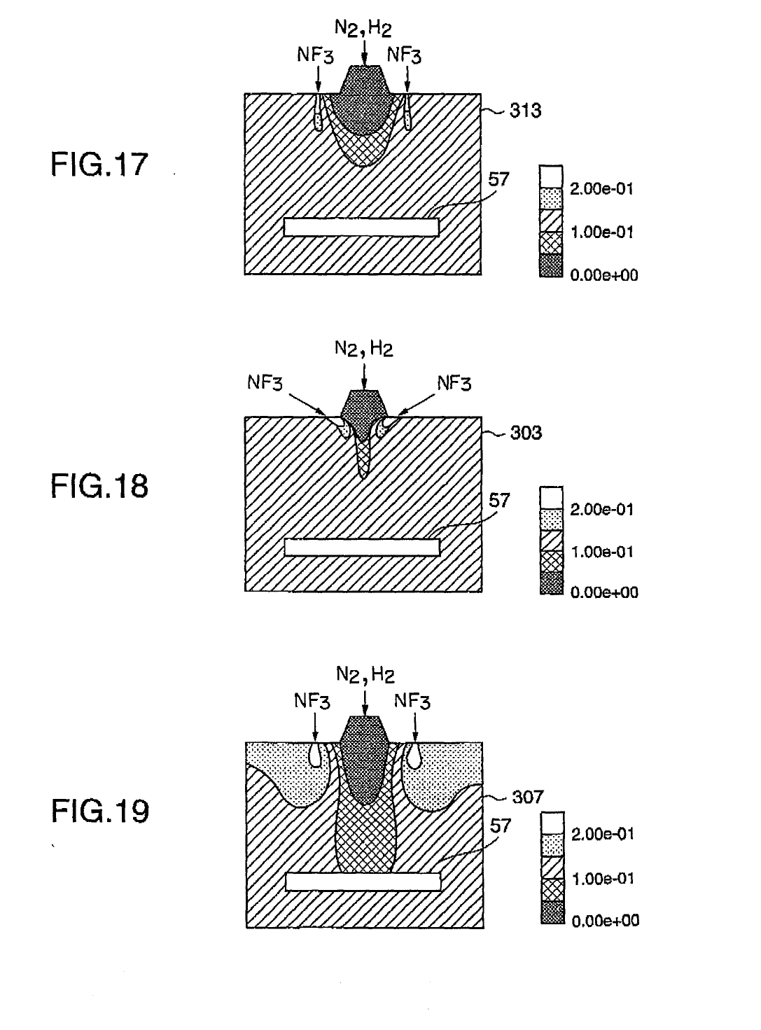

While, the NF₃ mole fraction distribution in the vertical direction of the processing container is shown in FIGS. 17 to 19. In the figures, FIG. 17 illustrates the analysis result for the processing apparatus 313 of FIG. 15. FIG. 18 illustrates the analysis result for the processing apparatus 303 of FIG. 10, while FIG. 19 illustrates the analysis result for the processing apparatus 307 of FIG. 12. Note, FIG. 19 also shows a section taken along a line XIX-XIX of FIG. 14.

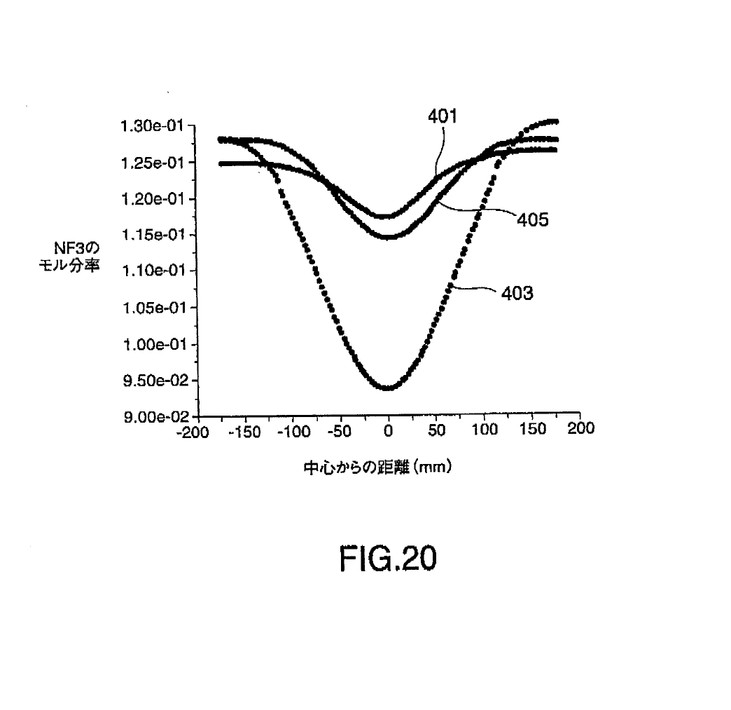

FIG. 20 shows the mole fraction distribution of the wafer in the diametrical direction for three processing containers shown in FIGS. 10, 12 and 15. In this figure, a graph line 401 designates the distribution in the processing container of FIG. 10, a graph line 403 the processing container of FIG. 12 and a graph line 405 designates the distribution in the processing container of FIG. 15.

From FIG. 18 and the graph line 401 of FIG. 20, it is obviously found that the NF₃ mole fraction distribution on the wafer has the highest uniformity in case of the arrangement of FIG. 10 where the nozzle orifices are inclined, which is more appropriate than the arrangement of FIG. 15.

On the other hand, in the arrangement of FIG. 12 where the nozzle orifices are arranged in double, there is a remarkable difference in mole fraction between the wafer's center and periphery while exhibiting an uneven uniformity, as obvious from FIG. 19 and the graph line of FIG. 20.

As this reason, it is presumed that the flowing speed of NF₃-gas through the nozzle orifices is lowered to effect an insufficient reaction between NF₃-gas and the activated seeds of N₂ and H₂ because the nozzle orifices are arranged in double and further the number of nozzle orifices is twice as many as that in the arrangement of FIG. 15.

In order to solve such a drawback, it is recommended to eject both N₂-gas and H₂-gas together with NF₃-gas through the nozzle orifices simultaneously thereby to prevent the deterioration in flowing speed of gas, in view of accomplishing the sufficient reaction between NF₃-gas and the activated seeds of N₂ and H₂. Alternatively, from the same point of view, it is recommended to increase the inner diameter of each nozzle orifice thereby to increase the flowing speed of gas.

As mentioned above, since the processing apparatus 51 has the activated-gas seeds induction port 79 and the nozzle orifices 105 formed in the top plate 71 opposing the wafer W on the mounting table 57 in the processing container 53, the activated gas seeds of N₂ and H₂ are sufficiently mixed with the processing gas of NF₃ into its uniform activation, whereby the uniform processing can be performed all over the substantial processed surface of the wafer.

Thus, since the processing apparatus is adapted so as to remove the generative film resulting from the reaction of the activated NF₃-gas with the oxidation film on the wafer, it is possible to perform the removal of oxidation film on the wafer uniformly.

Additionally, since the activated-gas seeds induction port 79 is arranged so that the gas ejected therethrough directs the center part of the wafer W and further the nozzle orifices 105 as a plural are arranged apart from each other in the periphery or the activated-gas seeds induction port 79 in the circumferential direction, the activated gas seeds of N₂ and H₂ enter into the processing container while being surrounded by NF₃-gas. Accordingly, it is possible to effectively activate NF₃-gas owing to its uniform mixing with the activated gas seeds of N₂ and H₂, allowing the wafer to be processed evenly.

Further, since the nozzle orifices 105 are arranged so that the ejecting direction extends along the ejecting direction of the activated-gas seeds induction port 79, both N₂/H₂activated gas seeds and NF₃-gas flow into the processing container, in parallel with each other as if NF₃-gas surrounded the N₂/H₂ activated gas seeds. Accordingly, it is possible to effectively activate NF₃-gas owing to its uniform mixing with the activated gas seeds of N₂ and H₂, allowing the wafer to be processed evenly.

Since the activated-gas seeds induction port 79 is provided, at its part close to the space in the processing container 53, with the inner circumferential surface 80 which is funnel-shaped so as to gradually increase its diameter as approaching the space in the processing container, it is possible to supply the whole area of the wafer with the activated-gas seeds, thereby allowing the wafer to be processed evenly.

Moreover, as it will be understood from the above experimental results, since the nozzle orifices 105 are disposed in respective positions less than 65 mm from the opening edge of the activated-gas seeds induction port 79, it is possible to make the NF₃-gas density on the wafer uniform.

Again, it is noted that the top plate 71 includes the plate body 73 and the nozzle plate 75 detachably laid on the underside of plate body 73. Further, in the superposition plane where the nozzle plate 75 and the plate body 73 are laid to overlap each other, the gas reservoir 103 is defined so as to surround the activated-gas seeds induction port 79. The plate body 73 has the communication hole 109 formed to communicate with the gas reservoir 103 from the outside of the plate body 73 thereby to supply NF₃-gas into the gas reservoir 103, while the nozzle plate 105 has the nozzle orifices 105 formed so as to extend from the gas reservoir 103 to the inside space of the processing container 53. Accordingly, if there are previously prepared a number of nozzle plates 75 which are modified in terms of the arrangement of the nozzle orifices 105, their distribution, their ejection angles, etc., then it is possible to make an exchange of the nozzle plate in accordance with the change of processing conditions, such as diameter of wafer, accomplishing the most suitable processing.

Again, since the nozzle orifices 105 are arranged so that the ejecting direction extends along the ejecting direction of the activated-gas seeds induction port 79, both N₂/H₂ activated gas seeds and NF₃-gas flow into the processing container, in parallel with each other as if NF₃-gas surrounded the N₂/H₂ activated gas seeds. Accordingly, it is possible to effectively activate NF₃-gas owing to its uniform mixing with the activated gas seeds of N₂ and H₂, allowing the wafer to be processed evenly.

Also noted, the above processing system 201 includes the low-temperature processing chambers 207 each having the processing apparatus 51, the heating chamber 209 having heating means for heating the wafer W and also allowing the generative film, which has been produced by the low-temperature process in the low-temperature processing chambers 207, to be heated up to a designated temperature for evaporation thereby removing the generative film from the wafer W, and the transfer chamber 203 having transfer means for transferring the wafer W between the low-temperature processing chambers 207 and the heating chamber 209. Additionally, since the low-temperature processing chambers 207 and the heating chamber 209 are provided independently of each other, it can be prevented that the heat produced in the heating process for the previously-processed wafer is remained to exert a bad influence on the low-temperature process on a sequent wafer.

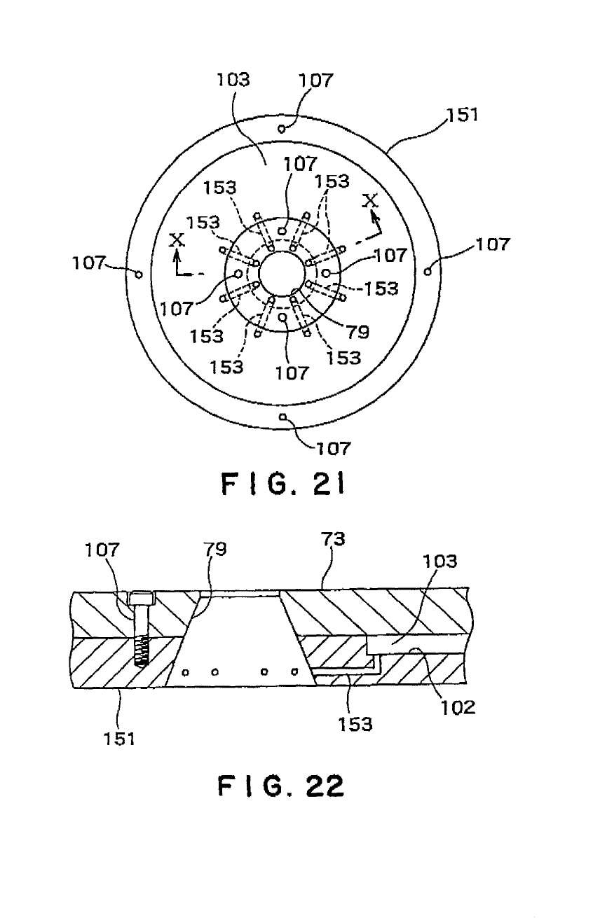

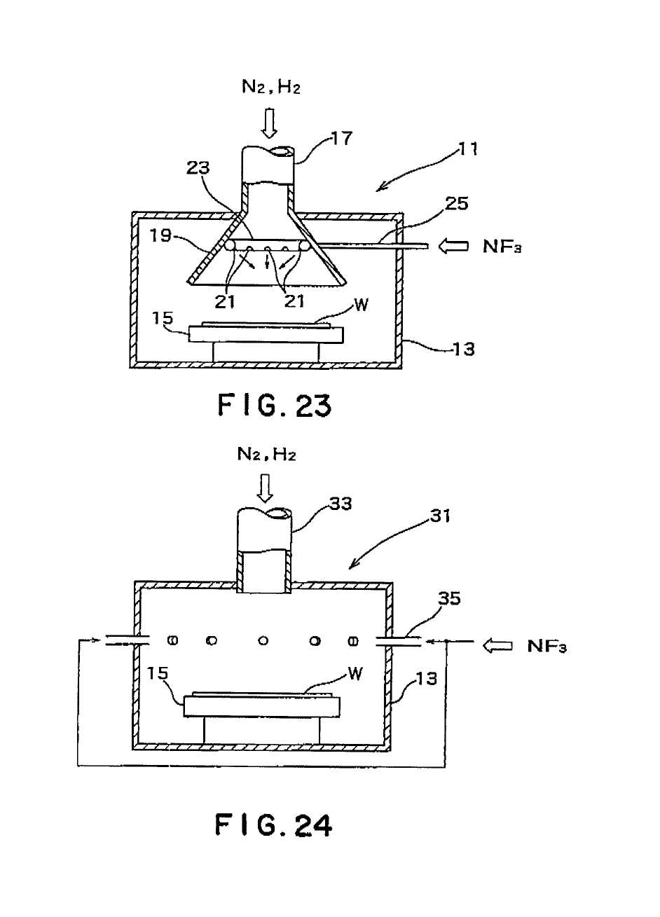

Next, FIG. 21 and FIG. 22 show a nozzle plate 151 capable of using in place of the nozzle plate 75 of FIG. 2. Different from the nozzle plate 75 shown in FIGS. 2 and 3, the nozzle plate 151 has nozzle orifices 153 formed to open at the inner circumferential surface 80 of the activated-gas seeds induction port 79. Each nozzle orifice 153 originates from the bottom of the annular recess 102 defining the gas reservoir 103 downwardly. Subsequently, the orifice 153 directs inward in the radial direction and finally opens at the inner circumferential surface 80 of the activated-gas seeds induction port 79. Further, the circumferential position of each nozzle orifice 153 is shifted from the adjacent bolt 107 by 22.5° in the circumferential direction so that the nozzle orifices 153 do not interfere with the bolts 107.

With the arrangement constructed as above, it allows the nozzle orifices 153 to open at the inner circumferential surface 80 of the activated-gas seeds induction port 79. Thus, since the supply port for the N₂/H₂ activated gas seeds can be arranged closer to the supply ports for NF₃-gas, it is possible to mix the N₂/H₂ activated gas seeds with NF₃-gas effectively and uniformly. That is, since the activated NF₃-gas is distributed over the wafer more uniformly, it is possible to accomplish the equalization in processing the wafer.

Note, although the above embodiments have been described with an example of installing the processing apparatus 51 in the processing system 201, it is not necessarily limited to this arrangement. Thus, the processing apparatus 51 may be used independently or in combination with the other apparatus.

As mentioned above, since the first-gas supply port and the second-gas supply port of the present invention are formed in the opposite wall forming the processing container and also facing the object to be processed, the activity of the first gas is hard to be lost and it is possible to mix the first gas and the second gas sufficiently. Accordingly, it is possible to distribute the second gas activated by the first gas on activation sufficiently uniformly, accomplishing an uniform processing on the object to be processed.

What is claimed is:

1. A processing apparatus comprising:
a processing container in which an object to be processed is arranged;
a first-gas supply port for supplying an interior of the processing container with a first gas on activation; and
a second-gas supply port for supplying a second gas activated by the first gas, the processing apparatus allowing the first gas to activate the second gas thereby processing the object by the second gas on activation;
wherein the first-gas supply port and the second-gas supply port are formed in an opposite wall forming the processing container, the opposite wall being arranged so as to face the object to be processed.

2. A processing apparatus as claimed in claim 1, wherein the first-gas supply port is arranged so that a direction of gas ejected through the first-gas supply port points to a center portion of the object to be processed, and the second-gas supply ports as a plural are arranged apart from each other around the first-gas supply port in a circumferential direction thereof.

3. A processing apparatus as claimed in claim 2, wherein the second-gas supply ports are arranged so that a direction of gas ejected through the second-gas supply ports extends along the direction of gas ejected through the first-gas supply port.

4. A processing apparatus as claimed in claim 2 or 3, wherein the first-gas supply port has an inner circumferential surface close to a space in the processing container, the inner circumferential surface being tapered so as to gradually increase a diameter of the first-gas supply port as approaching the space in the processing container.

5. A processing apparatus as claimed in any one of claims 2 to 4, wherein the second-gas supply ports open at an inner circumferential surface of a first-gas supply port's part close to a space in the processing container.

6. A processing apparatus as claimed in any one of claims 2 to 4, wherein the second-gas supply ports are positioned apart from an open edge of the first-gas supply port but less than 65 mm therefrom.

7. A processing apparatus as claimed in claim 2, wherein
the opposite wall provided with the first-gas supply port includes an opposite-wall body and a nozzle plate overlaid on an inside of the opposite-wall body;
a superposition plane where the nozzle plate and the opposite-wall body are laid to overlap each other has a gas reservoir formed so as to surround the first-gas supply port annularly;
the opposite-wall body has a communication hole formed to allow an outside of opposite-wall body to communicate with the gas reservoir thereby to supply the second gas to the gas reservoir; and
the nozzle plate has the second-gas supply ports formed so as to begin with the gas reservoir and also open at an inside space of the processing container.

8. A processing apparatus as claimed in claim 7, wherein the gas reservoir is defined between the opposite-wall body and an annular recess formed in the superposition plane of the nozzle plate.

9. A processing apparatus as claimed in claim 7 or 8, wherein the nozzle plate is detachably fixed to the opposite-wall body.

10. A processing apparatus as claimed in any one of claims 7 to 9, wherein the second-gas supply ports are formed so that a direction of gas ejected through the second-gas supply ports extends along the direction of gas ejected through the first-gas supply port.

11. A processing apparatus as claimed in any one of claims 7 to 9, wherein the second-gas supply ports are formed to begin with the gas reservoir and also open at an inner circumferential surface of the first-gas supply port close to a space in the processing container.

12. A processing apparatus as claimed in any one of claims 1 to 11, wherein the first gas is a mixture of N₂-gas and H₂-gas, while the second gas is NF₃-gas.

13. A processing apparatus as claimed in any one of claims 1 to 12, wherein the processing apparatus is adapted so as to allow the second gas to react with an oxidation film on a surface of the object to be processed thereby to produce a generative film.

14. A processing system for removing an oxidation film formed on an object to be processed, comprising:
a first processing chamber having a processing apparatus claimed in claim 13;
a second processing chamber having heating means for heating the object to be processed and also allowing the heating means to heat a generative film produced in the first processing chamber up to a designated temperature for evaporation thereby removing the generative film from the object; and
transfer means for transferring the object to be processed between the first processing chamber and the second processing chamber.
